(19) United States
(12) Patent Application Publication
(10) Pub. No.: US 2025/0253227 A1
(43) Pub. Date: Aug. 7, 2025

(54) CONDUCTIVE WIRINGS AND INTERCONNECT STRUCTURES AND INTEGRATED CIRCUIT DEVICES

(71) Applicants: Samsung Electronics Co., Ltd., Suwon-si (KR); IUCF-HYU (Industry-University Cooperation Foundation Hanyang University), Seoul (KR)

(72) Inventors: Tae Won JEONG, Suwon-si (KR); Changhwan CHOI, Seoul (KR); Sangwon KIM, Suwon-si (KR); Hyeong Jun KIM, Seoul (KR)

(21) Appl. No.: 19/047,564

(22) Filed: Feb. 6, 2025

(30) Foreign Application Priority Data
Feb. 7, 2024 (KR) 10-2024-0019141

(51) Int. Cl. H01L 23/498; H01L 21/324

(52) U.S. Cl. CPC H01L 23/49838; H01L 21/324; H01L 23/49822; H01L 23/49866

(57) ABSTRACT

A conductive wiring includes an alloy including cobalt and palladium. An interconnect structure includes one or more dielectric layers, and the conductive wiring positioned on at least one selected from the upper, lower, and side portions of the dielectric layer.

### CROSS-REFERENCE TO RELATED APPLICATION

This application claims priority to Korean Patent Application No. 10-2024-0019141, filed on Feb. 7, 2024, and all the benefits accruing therefrom under 35 U.S.C. § 119, the content of which in its entirety is herein incorporated by reference.

### BACKGROUND

### (a) Field

Embodiments of the disclosure relate to a conductive wiring, an interconnect structure including the conductive wiring and an integrated circuit device including the interconnect structure.

### (b) Description of the Related Art

In order to provide a high-performance integrated circuit device, technologies to reduce dimensions of the unit devices in the integrated circuit device have been studied. When dimensions of the unit devices in the integrated circuit device is reduced, the line width of the wirings electrically connecting the unit devices may also be reduced.

### SUMMARY OF THE INVENTION

When the line width of a wiring is reduced below a predetermined range, the resistance may rapidly increase due to material limitations, resulting in deterioration of electrical properties.

An embodiment provides a conductive wiring capable of reducing or preventing deterioration of electrical characteristics while having a reduced line width.

Another embodiment provides an interconnect structure including the conductive wiring.

Another embodiment provides an integrated circuit device including the conductive wiring or the interconnect structure.

According to an embodiment, a conductive wiring includes an alloy including cobalt and palladium.

In an embodiment, the palladium may be included in less than about 50 atomic percent (at %) based on a total number of atoms of the cobalt and the palladium.

In an embodiment, the alloy may be represented by Co₁₋ₓPdₓ (0<x≤0.40).

In an embodiment, a line width of the conductive wiring may be less than about 10 nanometers (nm).

In an embodiment, a change in a resistivity of the conductive wiring according to a 10% decrease in the line width at the line width of less than about 10 nm may be less than twice.

In an embodiment, a resistivity of the conductive wiring may be less than or equal to about 30 microhm-centimeter (μΩcm).

In an embodiment, the conductive wiring may satisfy the following Inequality:

$$0 < \frac{ρ 2 - ρ 1}{ρ 1} < 0.9 ,$$

where ρ1 is a resistivity of the conductive wiring at a line width of about 25 nm, and ρ2 is a resistivity of the conductive wiring at a line width of about 8 nm.

According to an embodiment, a method of manufacturing the conductive wiring includes providing sequentially or simultaneously cobalt and palladium to form a deposited product including cobalt and palladium, and annealing the deposited product at a temperature in a range of about 200° C. to about 500° C. to obtain the conductive wiring including the alloy including cobalt and palladium.

In an embodiment, the annealing the deposited product may include supplying hydrogen gas and nitrogen gas.

In an embodiment, each of the deposited product and the conductive wiring may have a line width of less than about 10 nm, and a resistivity of the conductive wiring may be lower than a resistivity of the deposited product.

According to an embodiment, an interconnect structure includes one or more dielectric layers, and the conductive wiring positioned on at least one selected from the upper, lower, and side portions of the dielectric layer.

In an embodiment, the dielectric layer may define a trench, and the conductive wiring may be embedded in the trench.

In an embodiment, the conductive wiring may include a first conductive wiring, a second conductive wiring positioned at a height from a height at which the first conductive wiring is positioned, and a via electrically connecting the first conductive wiring and the second conductive wiring to each other.

In an embodiment, the palladium may be included in an amount of less than about 50 at % based on a total number of atoms of the cobalt and the palladium included in the conductive wiring.

In an embodiment, the conductive wiring may include an alloy represented by Co₁₋ₓPdₓ (0<x≤0.40).

In an embodiment, a line width of the conductive wiring may be less than about 10 nm.

In an embodiment, a resistivity of the conductive wiring may be less than or equal to about 30 μΩcm.

In an embodiment, a change in a resistivity according to a 10% decrease in the line width of the conductive wiring may be less than twice.

According to an embodiment, an integrated circuit device includes the conductive wiring or the interconnect structure.

In an embodiment, the integrated circuit device may further include a transistor, a capacitor, a diode, a resistor, or a combination thereof, which is electrically connected to the conductive wiring or the interconnect structure.

In such embodiments, deterioration of electrical characteristics may be substantially reduced or effectively prevented while reducing the line width of the conductive wiring.

### BRIEF DESCRIPTION OF THE DRAWINGS

FIG. 1 is a cross-sectional view showing an interconnect structure according to an embodiment,

FIG. 2 is a cross-sectional view showing an interconnect structure according to another embodiment,

FIG. 3 is a cross-sectional view showing an interconnect structure according to another embodiment,

FIG. 4 is a conceptual diagram showing an electronic device according to an embodiment, and

FIG. 5 is an X-ray diffraction (XRD) graph showing changes of crystallinity of the Co—Pd alloys before and after a forming gas annealing (FGA) process in the conductive wirings according to Examples 1 and 2.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the drawings, the thickness of layers and regions may be exaggerated for clarity, and like reference numerals designate like elements throughout the specification.

It will be understood that when an element such as a layer, film, region, or substrate is referred to as being “on” or “above” another element, it can be “directly on” the other element or intervening elements may also be present therebetween. In contrast, when an element is referred to as being “directly on” another element, there are no intervening elements present.

The drawings and description are to be regarded as illustrative in nature and not restrictive. Like reference numerals designate like elements throughout the specification.

It will be understood that when a component is referred to as being “on” or “over” another component, the component can be directly on, under, on the left of, or on the right of the other component, or can be on, under, on the left of, or on the right of the other component in a non-contact manner.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure.

Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs.

It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The term “layer” includes a construction having a shape formed on a part of a region, in addition to a construction having a shape formed on an entire region.

As used herein, the term “the” or similar indicative terms correspond to both the singular form and the plural form. The steps of all methods described herein can be performed in any suitable order unless otherwise indicated herein or otherwise clearly contradicted by context.

Also, terms such as “unit.” “module,” etc., as used in the present specification may refer to a part for processing at least one function or action and may be implemented as hardware, software, or a combination of hardware and software.

The connecting lines, or connectors shown in the various figures presented are intended to represent example functional relationships and/or physical or logical couplings between the various elements.

It should be noted that many alternative or additional functional relationships, physical connections or logical connections may be present in a practical apparatus.

As used herein, “at least one selected from A, B, and C,” “at least one of A, B, or C,” “one of A, B, C, or a combination thereof” and “one of A, B, C, and a combination thereof” refer to each constituent element, and a combination thereof (e.g., A; B; C; A and B; A and C; B and C; or A, B and C).

Herein, “combination thereof” refers to a mixture, a stacked structure, a composite, an alloy, a blend, for example.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within +10%, +5%, +3%, or +1% of the indicated value or within a standard deviation. Hereinafter, “metal” is interpreted as a concept including metals and metalloids (semimetals).

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a conductive wiring according to an embodiment will be described.

The conductive wiring according to an embodiment may include any wiring that transmits an electrical signal or is used for an electrical connection, and may include, for example, any wiring electrically connected between active elements, passive elements, and/or between active elements and passive elements in a semiconductor device.

The conductive wiring may have a three-dimensional structure having a width, a length, and a thickness, herein a length direction (x-direction) of the conductive wiring may be a direction in which electrons transfer and may be perpendicular to the width direction (y-direction) and the thickness direction (z-direction), respectively.

The line width of the conductive wiring may be in a range of a nanometer (nm) to tens of nanometers, for example, less than about 20 nm, less than about 15 nm, less than about 10 nm, less than about 9 nm, less than about 8 nm, less than about 7 nm, less than about 5 nm, greater than or equal to about 1 nm and less than about 20 nm, greater than or equal to about 1 nm and less than about 15 nm, greater than or equal to about 1 nm and less than about 10 nm, about 1 nm to about 9 nm, about 1 nm to about 8 nm, about 1 nm to about 7 nm, or about 1 nm to about 5 nm.

The conductive wiring may include a cobalt (Co)-based alloy, and may include an alloy including Co and palladium (Pd) (hereinafter, Co—Pd alloy).

The Co may be a metal having a relatively low resistivity and a base material of the Co—Pd alloy and Pd may be a metal having a relatively short electron mean free path, and electron scattering at the surface and grain boundaries of the conductive wiring having a fine line width of a nanometer to tens of nanometers may be substantially reduced or effectively prevented, and thus substantially reduce or effectively prevent a rapid increase in the resistivity of the conductive wiring.

In an embodiment, the Co may be included more than the Pd in the Co—Pd alloy, and the Pd may be included in an amount of less than about 50 atomic percent (at %) based on the total number of atoms of the Co and the Pd included in the Co—Pd alloy.

In an embodiment, the Pd may be included, for example greater than 0 and less than or equal to about 45 at %, greater than 0 and less than or equal to about 43 at %, greater than 0 and less than or equal to about 40 at %, greater than 0 and less than or equal to about 38 at %, greater than 0 and less than or equal to about 35 at %, greater than 0 and less than or equal to about 34 at %, greater than 0 and less than or equal to about 33 at %, about 2 at % to about 45 at %, about 2 at % to about 43 at %, about 2 at % to about 40 at %, about 2 at % to about 38 at %, about 2 at % to about 35 at %, about 2 at % to about 33 at %, about 5 to about 43 at %, about 5 at % to about 43 at %, about 5 at % to about 40 at %, about 5 at % to about 38 at %, about 5 at % to about 35 at %, about 5 at % to about 34 at %, about 5 at % to about 33 at %, about 7 to about 45 at %, about 7 at % to about 43 at %, about 7 to about 40 at %, about 7 at % to about 38 at %, about 7 at % to about 35 at %, about 7 to about 34 at %, about 7 at % to about 33 at %, about 10 at % to about 45 at %, about 10 to about 43 at %, about 10 to about 40 at %, about 10 at % to about 38 at %, about 10 at % to about 35 at %, about 10 at % to about 34 at %, or about 10 at % to about 33 at %, with respect to the total number of atoms of the Co and the Pd in the Co—Pd alloy.

The Co—Pd alloy may further include one or more other metal atoms and/or non-metal atoms in addition to the Co and the Pd, such as oxygen atom. The content of oxygen atom may be less than the content of the Co or the Pd in the Co—Pd alloy.

In an embodiment, for example, the Co—Pd alloy may be represented by Co₁₋ₓPdₓ, where x is 0<x<0.50, 0<x≤0.45, 0<x≤0.43, 0<x≤0.40, 0<x≤0.35, 0<x≤0.34, 0<x≤0.33, 0.02≤x≤0.50, 0.02≤x≤0.45, 0.02≤x≤0.43, 0.02≤x≤0.35, 0.02≤x≤0.35, 0.02≤x≤0.35, 0.02≤x≤0.33, 0.02≤x≤0.33, 0.02≤x≤0.33, 0.05≤x≤0.45, 0.05≤x≤0.43, 0.05≤x≤0.40, 0.05≤x≤0.40, 0.05≤x≤0.35, 0.05≤x≤0.35, 0.05≤x≤0.35, 0.05≤x≤0.33, 0.10≤x≤0.34, or 0.10≤0.33.

In an embodiment, the Co—Pd alloy may be an alloy treated by annealing at a predetermined temperature, and as described later, atoms in the alloy are rearranged by annealing at the predetermined temperature, vacancies in grains may be reduced, and crystallinity may be increased, thereby having electrical characteristics and film properties different from those of a Co alone deposited product, a Pd alone deposited product, and/or a simple co-deposited product of un-annealed Co and Pd. In an embodiment, where the Co—Pd alloy may be applied to the conductive wiring having the above-described fine line width (e.g., less than about 20 nm, less than about 15 nm, or less than about 10 nm), the above-described electron scattering reduction effect may be further enhanced to substantially reduce or effectively prevent a rapid increase in resistivity of the conductive wiring.

For example, in an embodiment of the conductive wiring having a fine line width of less than about 10 nm, a change in resistivity of the conductive wiring according to a 10% decrease in a line width may be less than about twice. That is, the resistivity of the conductive wiring when a line width is decreased by 10% may be less than about twice the resistivity of the conductive wiring when the line width is not decreased. In such an embodiment, a change in resistivity of the conductive wiring according to a 10% decrease in a line width may be about 1.0 to 1.8 times, about 1.0 to 1.6 times, or about 1.0 to 1.4 times.

For example, in an embodiment of the conductive wiring having a fine line width of less than about 10 nm, the resistivity of the conductive wiring may be less than or equal to about 30 microhm-centimeter (μΩcm). In such an embodiment, the resistivity of the conductive wiring may be about 28 μΩcm or less, about 26 μΩcm or less, or about 25 μΩcm or less, and within the above range, about 2 μΩcm to about 30 μΩcm, about 2μΩcm to about 28 μΩcm, about 2 μΩcm to about 26 μΩcm, about 2 μΩcm to about 25 μΩcm, about 5μΩcm to about 30 μΩcm, about 5μΩcm to about 28 μΩcm, about 5μΩcm to about 26 μΩcm about 5μΩcm to about 25μΩcm, about 10 μΩcm to about 30 μΩcm about 10 μΩcm to about 28 μΩcm about 10 μΩcm to about 26 μΩcm, or about 10 μΩcm to about 25 μΩcm.

In an embodiment, unlike typical bulk metals such as copper (Cu), the conductive wiring including the Co—Pd alloy may not exhibit a rapid increase in resistivity of the fine line widths of less than about 10 nm, for example, the resistivity of the conductive wiring with a line width greater than 20 nm (e.g., line width 25 nm) and the conductive wiring with a line width less than 10 nm (e.g., line width 8 nm) may satisfy the following Inequality 1.

$$0 < \frac{ρ 2 - ρ 1}{ρ 1} < 0.9 \qquad [ Inequality 1 ]$$

In the Inequality 1, ρ1 denotes a resistivity of the conductive wiring at a line width of about 25 nm, and ρ2 denotes a resistivity of the conductive wiring at a line width of about 8 nm.

In such an embodiment, the conductive wiring including the Co—Pd alloy may further satisfy the following Inequality 1a.

$$0 < \frac{ρ 2 - ρ 1}{ρ 1} \leq 0.75 \qquad [ Inequality 1 a ]$$

In such an embodiment, the conductive wiring including the Co—Pd alloy may further satisfy the following Inequality 1b.

$$0 < \frac{ρ 2 - ρ 1}{ρ 1} \leq 0.5 \qquad [ Inequality 1 b ]$$

In an embodiment, as described above, the conductive wiring including the Co—Pd alloy may exhibit stable conductivity without a rapid increase in resistivity even at a fine line width (e.g., less than about 20 nm, less than about 15 nm, or less than about 10 nm).

Hereinafter, an embodiment of a method of manufacturing the conductive wiring according to the disclosure will be described.

The method of manufacturing the conductive wiring according to an embodiment may include providing sequentially or simultaneously Co and Pd to form a deposited product including Co and Pd, and annealing the deposited product to form the conductive wiring including the Co—Pd alloy.

The deposited product including Co and Pd (hereinafter, Co—Pd deposited product) may be formed through physical vapor deposition (PVD) such as sputtering or chemical vapor deposition (CVD). Here, the Co—Pd deposited product may be a thin film that is not annealed after the PVD or CVD described above.

The Co—Pd deposited product may have a three-dimensional structure with a width, length and thickness, such as the conductive wiring, which is a final structure, and may have a line width of less than about 20 nm, for example, less than about 15 nm, less than about 10 nm, less than or equal to about 9 nm, less than or equal to about 8 nm, less than or equal to about 7 nm, less than or equal to about 5 nm, greater than or equal to about 1 nm and less than 20 nm, greater than or equal to about 1 nm and less than 15 nm, greater than or equal to about 1 nm and less than about 10 nm, about 1 nm to about 9 nm, about 1 nm to about 8 nm, about 1 nm to about 7 nm, or about 1 nm to about 5 nm.

A deposition rate and/or a deposition time of the Co and the Pd may be adjusted based on a desired composition ratio, and for example, the deposition rate and/or the deposition time may be adjusted in a way such that the Pd is less than about 50 at % with respect to the total number of atoms of the Co and the Pd. In addition to the Co and the Pd, one or more other metal atoms and/or non-metal atoms may be sequentially or simultaneously deposited, in which the metal atoms and/or non-metal atoms may be included less than the Co or the Pd.

In an embodiment, for example, the Co—Pd deposited product may have a multi-layer structure including, for example, a layer mainly arranged with Co atoms and a layer mainly arranged with Pd atoms, and may further include a small amount of oxygen atoms.

In an embodiment, for example, the annealing may be performed by a forming gas annealing (FGA) process, and may be performed by supplying a forming gas in which a small amount (for example, about 5% or less) of hydrogen gas (H₂) is mixed with a nitrogen gas (N₂) as a main gas (for example, about 95% or greater).

The FGA process may be performed at a temperature of less than or equal to about 500° C., for example, at a temperature of about 200 to about 500° C., about 250 to about 450° C., or about 280 to about 430° C., for about 5 minutes to 2 hours, about 10 minutes to 90 minutes, or about 10 minutes to 60 minutes.

By annealing the Co—Pd deposited product, the Co—Pd alloy with improved film quality and electrical characteristics may be obtained. Specifically, Co atoms and Pd atoms may be densely rearranged by increasing the diffusion of Co atoms and Pd atoms and reducing oxygen atoms in the deposited product by the forming gas annealing process, and thus effectively reducing the vacancies in the Co—Pd alloy, increasing the crystallinity, and further increasing the thin film density of the conductive wiring including the Co—Pd alloy.

In addition, the film quality of the Co—Pd alloy may be improved compared to the Co—Pd deposited product described above, and for example, the surface roughness of the conductive wiring including the Co—Pd alloy may be lower than that of the Co—Pd deposited product. Accordingly, the conductive wiring including the Co—Pd alloy may exhibit improved film quality and electrical characteristics than the Co—Pd deposited product.

In an embodiment, for example, the conductive wiring including the Co—Pd alloy may have a small change in electrical characteristics according to a line width. In an embodiment of the conductive wiring having a fine line width of less than about 10 nm, a change in resistivity of the conductive wiring according to a 10% decrease in a line width may be less than about twice. In such an embodiment, for example, a change in resistivity of the conductive wiring according to a 10% decrease in a line width may be about 1.0 to 1.8 times, about 1.0 to 1.6 times, or about 1.0 to 1.4 times.

In an embodiment of the conductive wiring having a fine line width of less than about 10 nm, the resistivity of the conductive wiring may be about 30 μΩcm or less. In such an embodiment, for example, the resistivity of the conductive wiring may be about 28 μΩcm or less, about 26 μΩcm or less, or about 25 μΩcm or less, and within the above range, about 2 μΩcm to about 30 μΩcm about 2μΩcm to about 28 μΩcm, about 2 μΩcm to about 26 μΩcm, about 2 μΩcm to about 25 μΩcm, about 5 μΩcm to about 30 μΩcm, about 5μΩcm to about 28 μΩcm, about 5μΩcm to about 26 μΩcm, about 5 μΩcm to about 25 μΩcm, about 10 μΩcm to about 30 μΩcm, about 10 μΩcm to about 28 μΩcm about 10 μΩcm to about 28 μΩcm about 10 μΩcm to about 26 μΩcm, or about 10μΩcm to about 25 μΩcm.

Unlike conventional bulk metals such as copper (Cu), an embodiment of the conductive wire including the Co—Pd alloy may not exhibit a rapid increase in resistivity at a fine line width of less than about 10 nm. In an embodiment, for example, the resistivity of the conductive wire with a line width greater than 20 nm (e.g., line width 25 nm) and conductive wires with a line width less than 10 nm (e.g., line width 8 nm) may satisfy the Inequality 1, the Inequality 1a, and/or the Inequality 1b above.

In such an embodiment, the conductive wiring may extend in a horizontal and/or vertical direction on a substrate (not shown), and may be embedded in a trench of a dielectric layer to form an interconnect structure electrically connecting one or more devices to each other.

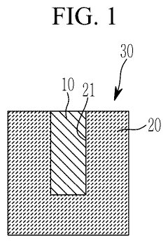

FIG. 1 is a cross-sectional view showing an interconnect structure according to an embodiment.

Referring to FIG. 1, an interconnect structure 30 according to an embodiment includes a dielectric layer 20 and a conductive wiring 10.

A substrate (not shown) may be disposed under the dielectric layer 20, and the substrate may be a semiconductor substrate. The semiconductor substrate may include, for example, a group IV semiconductor material, a group III-V semiconductor compound, or a group II-VI semiconductor compound, and may include, for example, the group IV semiconductor material including at least one selected from Si, Ge, Sn, C, B, Ga, In, and Al, the Group III-V compound semiconductor material in which at least one selected from B, Ga, In, and Al and at least one selected from N, P, As, Sb, S, Se, and Te are combined, or a group II-VI compound semiconductor material in which at least one of Be, Mg, Cd, and Zn and at least one selected from O, S, Se, and Te are combined. In an embodiment, for example, the semiconductor substrate may include Si, Ge, SiC, SiGeC, SiGeC, Ge alloy, GaAs, InAs, InP, or the like, but is not limited thereto.

At least one semiconductor device (not shown) may be included in and/or on the substrate, and for example, at least one selected from a transistor, a capacitor, a diode, and a resistor may be included, but is not limited thereto.

The dielectric layer 20 may include, for example, a (semi) metal oxide, a carbon-doped (semi) metal oxide, a (semi) metal carbide, a hydrogenated (semi) metal carbide, a (semi) metal nitride, a (semi) metal oxynitride, or a combination thereof. The dielectric layer 20 may include, for example, AlO_{z} (0<z≤3/2, for example, Al₂O₃), AlN, ZrOₓ (0<x≤2), HfOₓ (0<x≤2), SiO₂, SiCO, SiCN, SION, SiCOH, AlSiO, BN (boron nitride), or a combination thereof, but is not limited thereto. The dielectric layer 20 may include one or more trenches 21, that is, one or more trenches 21 are defined or formed in the dielectric layer 20. The trench 21 may have a narrow width of less than about 20 nm, less than about 15 nm, less than about 10 nm, less than or equal to about 9 nm, less than or equal to about 8 nm, less than or equal to about 7 nm, less than or equal to about 5 nm, greater than or equal to about 1 nm and less than about 20 nm, greater than or equal to about 1 nm and less than about 15 nm, greater than or equal to about 1 nm and less than about 10 nm, about 1 nm to about 9 nm, about 1 nm to about 8 nm, about 1 nm to about 7 nm, or about 1 nm to about 5 nm. The trench 21 may have a high aspect ratio (i.e., a ratio of width to depth), for example an aspect ratio of about 1:3 (width:depth) or greater, for example, about 1:3 to about 1:50.

The conductive wiring 10 may be positioned on at least one selected from the upper, lower, and side portions of the dielectric layer 20, and for example, the conductive wiring 10 may be embedded in the trench 21 of the dielectric layer 20. The conductive wiring 10 may include the Co—Pd alloy, which is the same as that described above, and any repetitive detailed description thereof will be omitted.

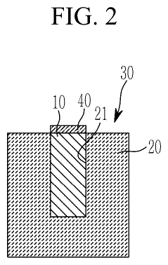

FIG. 2 is a cross-sectional view showing an interconnect structure according to another embodiment.

Referring to FIG. 2, the interconnect structure 30 according to another embodiment includes the dielectric layer 20 and the conductive wiring 10. In such an embodiment, as shown in FIG. 2, the interconnect structure 30 may further include an anti-scattering layer 40 on the surface of the conductive wiring 10. The anti-scattering layer 40 may effectively reduce electron scattering at the surface of the conductive wiring 10. The anti-scattering layer 40 may include graphene, metal-doped graphene, metal, or a combination thereof, but is not limited thereto.

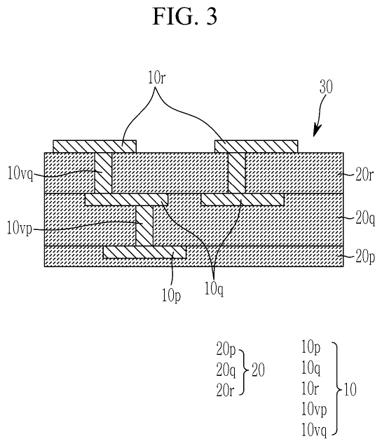

FIG. 3 is a cross-sectional view showing an interconnect structure according to another embodiment.

Referring to FIG. 3, the interconnect structure 30 according to another embodiment includes the dielectric layer 20 and the conductive wiring 10.

In such an embodiment, as shown in FIG. 3, the dielectric layer 20 may include a plurality of dielectric layers 20p, 20q, and 20r positioned at different heights (levels) from each other, and each of the dielectric layers 20p, 20q, and 20r may include a same material as each other or different materials from each other. Each of the dielectric layers 20p, 20q, and 20r may have a trench 21, and the conductive wiring 10 may be embedded in each trench 21.

The conductive wiring 10 may include a plurality of conductive wirings 10p, 10q, and 10r and a plurality of vias 10vp and 10vq positioned at different heights from each other. That is, the conductive wiring 10 may include the first conductive wiring 10p, the second conductive wiring 10p positioned at a different height from the first conductive wiring 10p (that is, at a height different from a height at which the first conductive wiring 10p is positioned), the third conductive wiring 10r positioned at a different height from the first and second conductive wirings 10p and 10q, a via 10vp connecting the first conductive wiring 10p and the second conductive wiring 10q to each other, and a via 10vq electrically connecting the second conductive wiring 10g and the third conductive wiring 10r to each other. However, it is not limited to this, and the interconnect structure 30 may further include another conductive wire positioned at different heights or horizontally from the first, second, and/or third conductive wires 10p, 10q, 10r, and another via electrically connecting the adjacent conductive wires positioned at different heights from each other.

The first, second, and third conductive wirings 10p, 10q, and 10r and the vias 10vp and 10vq may be the same as the conductive wirings 10 described above, and may include the Co—Pd alloy, as described above. Accordingly, any repetitive detailed description thereof will be omitted. In such an embodiment, the anti-scattering layer 40 shown in FIG. 2 may be further disposed or formed on surfaces of the first, second, and third conductive wirings 10p, 10q, and 10r, and/or the vias 10vp and 10vq.

The conductive wiring 10 and/or the interconnect structure 30 described above may be included in an integrated circuit device. The integrated circuit device may be a dynamic random-access memory (DRAM) or a logic device, but is not limited thereto. The integrated circuit device may include, for example, a unit device including a transistor, a capacitor, a diode, a resistor, or a combination thereof, electrically connected to the above-described conductive wiring 10. The integrated circuit device may be applied to, for example, a wiring (e.g., bit line, word line, etc.) connected to a unit device such as a transistor and/or a back end of line (BEOL) structure.

For example, the transistor may have various structures, such as fin field-effect transistor (FinFET), gate-all-around field-effect transistor (GAAFET), multi-bridge channel field effect transistor (MBCFET), complementary field effect transistor (CFET), or vertical field-effect transistor (VFET), but is not limited thereto. For example, the transistors may include a two-dimensional material as an active material and may be CFET, MBCFET, or carbon nanotube field effect transistor (CNT-FET), but are not limited to them.

The conductive wiring 10, the interconnect structure 30 and/or the integrated circuit device described above may be included in various electronic devices. The electronic devices may include, for example, mobile devices, computers, laptops, tablet computer, smart watches, sensors, digital cameras, electronic books, network devices, car navigators, Internet of Things (IoT), Internet of Everything (IoE), drones, door locks, safes, automated teller machines (ATM), security devices, medical devices, automobile electrical components, etc. but are not limited thereto.

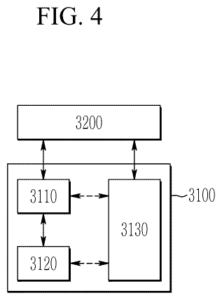

FIG. 4 is a conceptual diagram illustrating an electronic device according to an embodiment.

Referring to FIG. 4, the electronic device 3100 according to an embodiment may include a memory unit 3110, an arithmetic logic unit 3120, and a control unit 3130, which may be electrically connected to one another. In an embodiment, for example, the memory unit 3110, the arithmetic logic unit 3120, and the control unit 3130 may be defined by circuitry and implemented as one chip, for example, monolithically integrated on one substrate. The memory unit 3110, the arithmetic logic unit 3120, and the control unit 3130 may independently include a transistor, a capacitor, a diode, a resistor, or a combination thereof. The electronic device 3100 may be connected to one or more input/output devices 3200.

Hereinafter, the embodiments are illustrated in more detail with reference to examples. However, these examples are exemplary, and the scope of the disclosure is not limited thereto.

### [Forming a Conductive Wiring]

### Example 1

The silicon wafers on which a 300 nm-thick silicon oxide film (SiO₂) is formed are put in each ultrasonic bath including isopropyl alcohol and deionized water and washed for 1 minute, and blown with nitrogen gas.

Subsequently, the temperature of the silicon wafers is raised to 300° C. and argon (Ar) is supplied at 40 standard cubic centimeter per minute (sccm) and the pressure is adjusted to 4×10⁻³ Torr. Then, in a direct-current (DC) magnetron sputtering system at a pressure of 2×10⁻⁶ Torr, DC powers are set to 50 watts and 30 watts, respectively, pre-sputtering the Co target and Pd target for 10 minutes, and the deposition time is adjusted in a way such that Co and Pd are deposited on the silicon oxide film at an atomic ratio of 0.9:0.1 to form a Co—Pd deposited product.

Then, a forming gas annealing (FGA) process is performed in an H₂/N₂ (about 5:95 volume ratio) atmosphere in the Co—Pd deposited product at 400° C. for 30 minutes to form a Co—Pd alloy, manufacturing conductive wirings with various thicknesses (line widths) from 5 nm to 25 nm.

### Example 2

Conductive wirings are manufactured in the same way as in Example 1, except that Co and Pd are deposited at an atomic ratio of 0.67:0.33 to form a Co—Pd deposited product.

### Comparative Example 1

A conductive wiring made of Co alone, instead of the Co—Pd alloy, is manufactured.

### [Evaluation I]

In the conductive wirings according to Examples, crystal structures of Co—Pd before and after the forming gas annealing (FGA) process are analyzed.

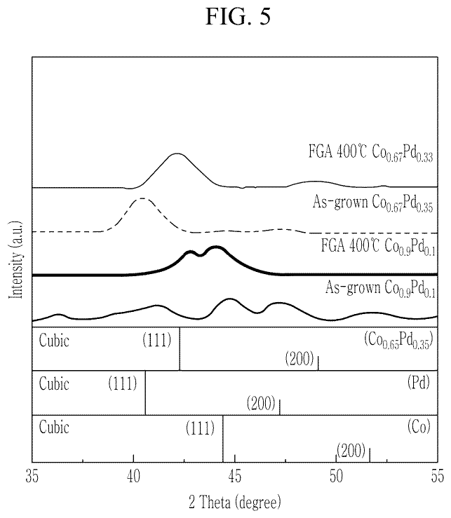

FIG. 5 is an X-ray diffraction (XRD) graph showing changes of crystallinity of the Co—Pd before and after a forming gas annealing (FGA) process in the conductive wirings according to Examples 1 and 2.

Referring to FIG. 5, it is confirmed that the XRD peaks are shifted after the forming gas annealing process (FGA) in the conductive wirings according to Examples 1 and 2, and from this, it is confirmed that crystallinity of the Co—Pd alloy may be improved in the forming gas annealing (FGA) process.

### [Evaluation II]

Compositions of Co and Pd in the conductive wiring according to Examples are analyzed.

The compositions of Co and Pd are analyzed by X-ray photoelectron spectroscopy (XPS).

The results are shown in Table 1.

TABLE 1

| | Co 2p (at %) | Pd 3d (at %) |
|---|---|---|
| Example 1 | 16.88 | 1.16 |
| Example 2 | 15.9 | 7.37 |

Referring to Table 1, it is confirmed that the conductive wiring according to Example 1 includes Co_{0.9}Pd_{0.1} alloy, and the conductive wiring according to Example 2 includes Co_{0.67}Pd_{0.33} alloy.

### [Evaluation III]

The resistivity of the conductive wirings according to Examples and Comparative Examples is evaluated.

The resistivity is calculated using the measured thickness of the thin film after measuring the sheet resistance with a 4-point probe (CMT-SR2000N).

The results are shown in Table 2.

TABLE 2

| | | Normalized Resistivity in Size |
|---|---|---|
| | Resistivity (μΩcm, @8 nm) | $( \frac{ρ 2 - ρ1}{ρ1} )$ |
| Example 1 | 19 | 0.46 |
| Example 2 | 25 | 0.25 |
| Comparative Example 1 | 34 | 1.18 |
| Reference Example (Cu) | 35 | 1.60 |

* Reference Example (Cu): MRS Bull. 46, 959 2021 (@10 nm)
* p1: Resistivity at a line width of 25 nm
* p2: Resistivity at a line width of 8 nm

Referring to Table 2, it is confirmed that the conductive wirings according to Examples has a lower resistivity and a lower resistivity change rate according to a line width as compared to the conductive wiring according to Comparative Example or the Cu wiring according to Reference Example.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A conductive wiring comprising an alloy including cobalt and palladium.

2. The conductive wiring of claim 1, wherein the palladium is included in less than about 50 at % based on a total number of atoms of the cobalt and the palladium.

3. The conductive wiring of claim 1, wherein the alloy is represented by Co₁₋ₓPdₓ (0<x≤0.40).

4. The conductive wiring of claim 1, wherein a line width of the conductive wiring is less than about 10 nm.

5. The conductive wiring of claim 4, wherein a change in a resistivity of the conductive wiring according to a 10% decrease in the line width at the line width of less than about 10 nm is less than twice.

6. The conductive wiring of claim 4, wherein a resistivity of the conductive wiring is less than or equal to about 30 μΩcm.

7. The conductive wiring of claim 1, wherein the conductive wiring satisfies the following inequality:
$$0 < \frac{ρ 2 - ρ 1}{ρ 1} < 0.9 ,$$
wherein
ρ1 denotes a resistivity of the conductive wiring at a line width of about 25 nm, and
ρ2 denotes a resistivity of the conductive wiring at a line width of about 8 nm.

8. A method of manufacturing the conductive wiring of claim 1, the method comprises:
providing sequentially or simultaneously cobalt and palladium to form a deposited product including cobalt and palladium, and
annealing the deposited product at a temperature in a range of about 200° C. to about 500° C. to obtain the conductive wiring including the alloy including cobalt and palladium.

9. The method of claim 8, wherein the annealing the deposited product comprises supplying hydrogen gas and nitrogen gas.

10. The method of claim 8, wherein
each of the deposited product and the conductive wiring has a line width of less than about 10 nm, and
a resistivity of the conductive wiring is lower than a resistivity of the deposited product.

11. An interconnect structure comprising:
one or more dielectric layers, and
the conductive wiring of claim 1 positioned on at least one selected from the upper, lower, and side portions of the dielectric layer.

12. The interconnect structure of claim 11, wherein
the dielectric layer defines a trench, and
the conductive wiring is embedded in the trench.

13. The interconnect structure of claim 11, wherein the conductive wiring comprises:
a first conductive wiring,
a second conductive wiring positioned at a height different from a height at which the first conductive wiring is positioned, and
a via electrically connecting the first conductive wiring and the second conductive wiring to each other.

14. The interconnect structure of claim 11, wherein the palladium is included in an amount of less than about 50 at % based on a total number of atoms of the cobalt and the palladium included in the conductive wiring.

15. The interconnect structure of claim 11, wherein the conductive wiring comprises an alloy represented by Co₁₋ₓPdₓ (0<x≤0.40).

16. The interconnect structure of claim 11, wherein a line width of the conductive wiring is less than about 10 nm.

17. The interconnect structure of claim 16, wherein a resistivity of the conductive wiring is less than or equal to about 30 μΩcm.

18. The interconnect structure of claim 16, wherein a change in a resistivity according to a 10% decrease in the line width of the conductive wiring is less than twice.

19. An integrated circuit device comprising the interconnect structure of claim 11.

20. The integrated circuit device of claim 19, further comprising a transistor, a capacitor, a diode, a resistor, or a combination thereof, which is electrically connected to the conductive wiring.
